(19) United States
(12) Patent Application Publication
(10) Pub. No.: US 2015/0325458 A1
(43) Pub. Date: Nov. 12, 2015

(54) METHOD AND SYSTEM TO IMPROVE DRYING OF FLEXIBLE NANO-STRUCTURES

(71) Applicant: Tokyo Electron Limited, Tokyo (JP)

(72) Inventor: Wallace PRINTZ, Austin, TX (US)

(21) Appl. No.: 14/710,395

(22) Filed: May 12, 2015

Related U.S. Application Data
(60) Provisional application No. 61/992,074, filed on May 12, 2014.

(51) Int. Cl. H01L 21/67

(52) U.S. Cl. CPC H01L 21/67051

(57) ABSTRACT

Disclosed herein are methods and systems for processing of nano-structures. In particular, disclosed herein are methods for processing nano-structures during semiconductor manufacturing, including nano-structures of drying high-aspect ratios. Also disclosed are systems for implementing the methods disclosed herein.

### CROSS-REFERENCE TO RELATED APPLICATIONS

This application claims priority from U.S. Provisional Application No. 61/992,074, filed on May 12, 2014, which is incorporated herein by reference in its entirety.

### BACKGROUND

Nano-structures are routinely manufactured in modern microfabrication processes. For example, during semiconductor processing, methods such as etching and laser scribing are used to create nano-structures densely populated within a small piece of substrate material such as silicon. After the nano-structures are formed on the substrate, it is necessary to remove residual chemicals and/or fine particles or debris to reveal the features of such nano-structures. This is often achieved by washing and drying steps. Nano-structure such as those with high-aspect ratios are prone to damage during washing and drying.

In the semiconductor processing context, the typical method of drying a patterned surface in a single-wafer processing tool is to rinse with water and spin-dry. As nodes shrink and pattern aspect ratios become higher, the rigidity a substrate material may no longer withstand the capillary and Laplace collapse forces of a wetted structure and the pattern may bend and ultimately collapse upon its neighboring patterns.

One method to overcome this collapse trend may be to use a lower surface tension liquid to displace the water prior to drying, by using alternative wash or rinse solvents such as isopropyl alcohol (IPA). However, IPA may no longer be sufficient to prevent collapse in semiconductor structures of high aspect ratio (AR), for example, those of about 13 and above in the case of silicon crystal. Surface modification of the structure to increase the contact angle of the wetting fluid may also be used, such as using self-assembled monolayers or silylation chemistry of Si-containing surfaces, but these approaches may have a high cost due to the silylation chemical supply cost combined with the volume of silylating chemical liquid spun on to the wafers. The sequence comparison of drying processes is shown in FIGS. 1A and 1B.

In FIG. 1A, the cleaning of a substrate surface may include rinsing with a rinsing agent such as water. At step 110, after miniaturized structures are created on a substrate in a patterned layer, the substrate surface may be wetted to initiate cleaning. At step 120, a rinsing agent may be applied to the substrate surface. The most commonly used rinsing agent in the semiconductor industry is water. Water replaces chemicals that may be on the substrate from the previous processing step(s). After the water rinse, miniaturized structures in the patterned layer on the substrate surface may be partially or completely immersed in water.

Drying off the water may occur before further processing. Water evaporates more slowly than some organic solvents. Alternative solvents such as isopropyl alcohol (IPA) may be used to displace surface water, as indicated in step 130.

During and after the rinsing steps, the substrate may be subject to a spin-dry step 1000. Here, the substrate may be placed on a spinning platform. When the platform spins, the rinsing agent may escape from the space between the miniaturized structures in the patterned layer and result in a dry substrate bearing clean miniaturized structures. In some embodiments, a gas stream may be applied in the drying step to push the liquid rinsing agent off the substrate surface and also enhance evaporation of the liquid.

Alternatively, solvent displacement may be combined with silylation treatment of the substrate surface to further prevent or reduce damages to the miniaturized structures in the patterned layer. An exemplary silylation-based washing and drying process is outlined in FIG. 1B. A silylation-based washing and drying process shares a few process steps as a traditional solvent displacement wash/dry process (e.g., steps 110, 120 and 130).

A difference between the processes in FIGS. 1A and 1B is that the latter includes a silylation procedure. Silylation generally refers to a process of introducing a silyl group (e.g., R₃Si, where R represents substituents) to a molecule. Here, silylation may be achieved when silyl groups are attached to substrate surface.

Starting at step 140, after an IPA rinse, the substrate may be further subject to a rinse with a silylation liquid to modify substrate surface by silylation reaction. The silylation rinse 140 may be followed by an IPA rinse 150, water rinse 160 and spin-dry step 1000.

When using an IPA-last drying process, some water may still remain between the structures (likely due to remaining water at the bottom of the structure that is not thoroughly removed during the IPA rinse) and this water may be responsible for collapsing the structures.

Surface modification by silylation in a conventional solvent displacement and silylation process (e.g., the one depicted in FIG. 1B) is further illustrated in FIG. 4A. A patterned layer (e.g., element 400) may include multiple miniaturized structures 410. For simplicity of illustration, elements 410 are shown as structures with identical shape and size. It will be understood that a patterned layer may also contain miniaturized structures 410 with different shapes and sizes.

After the substrate surface may be wetted, rinsing agent 430 may be trapped in the space between miniaturized structures 410. For an un-silylated patterned layer, miniaturized structures 410 may have unmodified surface 420, with which rinsing agent 430 may form low contact angles. Low contact angles may correspond to high surface tension and larger capillary and Laplace collapse forces and may lead to collapse of miniaturized structures 410.

During silylation, surfaces of individual miniaturized structures 410 may be converted into modified surface 440. In a conventional silylation process, silylation may be achieved by immersing miniaturized structures 410 in a liquid silylating agent (not shown). In particular, the liquid silylating agent may be applied to fill the space between miniaturized structures 410. As such, any liquid accessible surface of miniaturized structures 410 may be modified.

Enhanced hydrophobicity from silylation may change the surface properties of the substrate. In particular, it may allow rinsing agent 430 to form high contact angles with modified surface 440. High contact angles may correspond to smaller capillary and Laplace collapse forces, which allows better preservation of miniaturized structures 410, even when such structures have high aspect ratios. For example, untreated substrate surface may have contact angles much smaller than 90 degree, which correspond to large capillary forces. In contrast, silylated surfaces wetted with water may achieve contact angles above 90 degree, up to 110-120 degree or even higher, depending on reaction conditions (such as temperature environment humidity, etc.). In some embodiments, the optimum contact angle to reduce capillary forces may be 90 degree, which may be achieved through spin-on application of chemical reagent without additional reaction enhancements, for example, at standard process temperatures of 23-25° C.

In various embodiments of drying hardware, a scanning dispense arm may apply IPA substantially at the center of the wafer for a predetermined amount of time to displace water on the wafer surface. Following the center dispense, the arm may then scan towards the edge of the wafer while dispensing IPA. In some embodiments, the transition from water rinse to IPA rinse, may be “staged” by adding IPA to the dispensed water and then increasing gradually the concentration of IPA until no water is dispensed, only to thereafter commence the movement of the IPA dispense arm. Concurrently, but after the IPA dispense arm has moved away slightly from the wafer center, a second dispense arm may move to the center of the wafer and begin to dispense Nitrogen gas (N₂) in a narrow jet in order to quickly dry out the center of the wafer. The N₂ dispense arm may then scan towards the edge of the wafer (in the same or opposite direction than the IPA dispense arm) at a rate (speed) that may be equal to or different than the rate of the IPA arm scan, while dispensing N₂ gas such that the N₂ helps maintain the IPA meniscus from breaking up. The N₂ arm may have a dispense nozzle that is configured in a vertical direction or at some other fixed or variable angle relative to the wafer surface, for example 45 degrees, so as to enhance the shear force on the liquid and maximize the drying rate of the IPA while still maintaining a good meniscus shape (see FIGS. 5A and 5B). The IPA dispense arm and the N₂ dispense arms may be independently controlled and their positions and speeds regulated in a predetermined manner, by a controller (which can control other parameters of the process as well.)

FIGS. 5A and 5B illustrate a standard system set up for wetting, rinsing and drying a substrate bearing miniaturized structures. FIG. 5A shows the side view of a substrate bearing a patterned layer of miniaturized structures (e.g., element 400). In some embodiments, the substrate may be a semiconductor wafer bearing integrated circuit patterns or other miniaturized structures.

The substrate may be positioned on a spinning platform 500 that rotates along axis A-A′. The platform may be controlled to spin at a predetermined rotational speed. In some embodiments, rotation rates of the platform may be between 50 rpm (revolutions per minute) and 2000 rpm. In some embodiments, the rotation rate may be between 500 rpm and 1000 rpm. In general, the rotation rate may not be relevant to the size of the nano structures. In some embodiments, rotation rate may further be varied during drying. For example, the rotation rate may be reduced as dispense arms move radially outwards, the reduced rotation rate helping maintain a stable meniscus.

Two dispense arms may be positioned above the substrate for dispensing liquid or gas. For example, dispense arm 510 may dispense one or more rinsing agents such as water or IPA. The rinsing agent may be dispensed while platform 500 is spun such that the dispensed liquid (e.g., element 430) quickly spreads over the substrate surface to immerse the miniaturized structures. Dispense arm 520 may apply a nitrogen gas stream to substrate surface, starting from the center of the substrate to push the liquid rinsing agent towards the edge of the substrate.

FIG. 5B shows a top view of the substrate during the rinsing and drying steps. As the substrate spins and the nitrogen dispense arm moves from the center towards the edge of the substrate, the dry area may expand outward from the center while the wet area decreases and eventually disappears.

### DESCRIPTION OF THE DRAWINGS

Those of skill in the art will understand that the drawings, described below, are for illustrative purposes only. The drawings are not intended to limit the scope of the present teachings in any way.

FIG. 1A illustrates an exemplary embodiment known in the art.

FIG. 1B illustrates an exemplary embodiment known in the art.

FIG. 2 illustrates an exemplary embodiment.

FIG. 3 illustrates an exemplary embodiment known in the art.

FIG. 4A illustrates an exemplary embodiment known in the art.

FIG. 4B illustrates an exemplary embodiment.

FIG. 5A illustrates an exemplary embodiment known in the art.

FIG. 5B illustrates an exemplary embodiment known in the art.

FIG. 6A illustrates an exemplary embodiment.

FIG. 6B illustrates an exemplary embodiment.

FIG. 6C illustrates an exemplary embodiment.

FIG. 6D illustrates an exemplary embodiment.

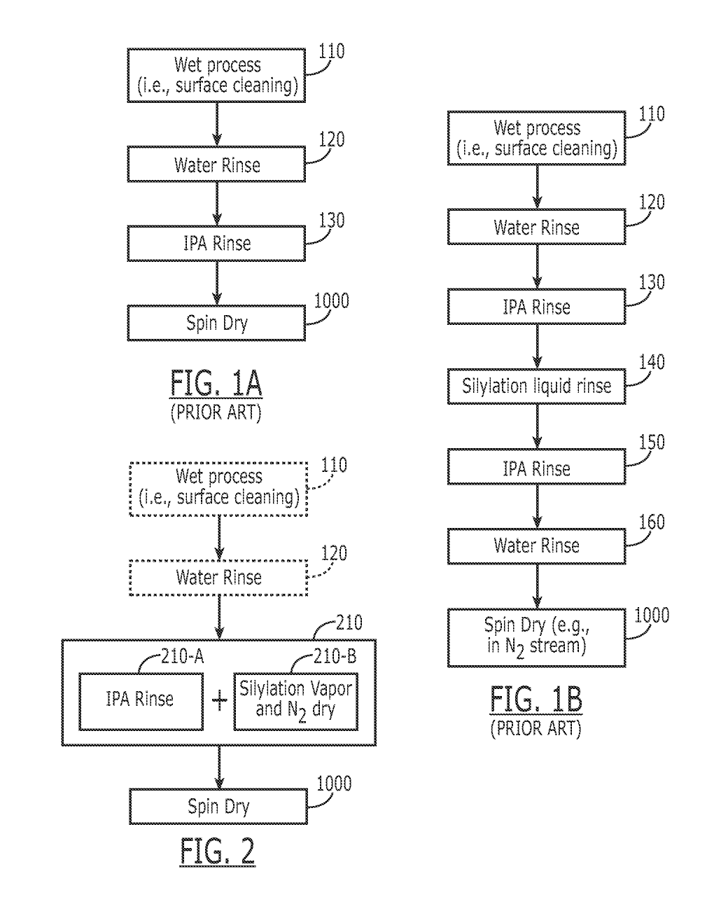

### DETAILED DESCRIPTION

Unless otherwise noted, terms are to be understood according to conventional usage by those of ordinary skill in the relevant art.

As used herein, the terms “silyl agent” or “silylating agent” refers to any agent that can undergo a silylation reaction. These terms are used interchangeably.

Microfabrication techniques are widely applied in modern manufacturing processes to create miniaturized structures of micrometer, nanometer or even smaller scales, resulting in a patterned layer on the surface of a substrate. Residual material left from the microfabrication processes may be removed in a surface cleaning process; for example, by washing the substrate surface with one or more rinsing agents before subjecting the substrate to one or more drying steps.

During the cleaning process, different rinsing agents may be used. As noted previously, a typical single-wafer cleaning process may start with rinsing the patterned surface on a semiconductor substrate with water and spin-dry. Wetting or rinsing and subsequent drying of the substrate surface may be most essential for a cleaning process.

When structural elements in the patterned surface become more fragile, for example, as nodes shrink and aspect ratios of miniaturized structures in the patterned layer increase, the rigidity of most standard substrate material may no longer withstand the capillary and Laplace collapse forces of a wetted structure. Consequently, miniaturized structures in the patterned layer may bend and may ultimately collapse. In some embodiments, the sizes of miniaturized structures vary according to the functionalities of the structures. For example, the structures can be as small as 7 nm for the logic gates, up to 500 nm or larger for metal levels, all on the same substrate but at different levels of hierarchy.

An exemplary process in accordance with the present method is depicted in FIG. 2. The process starts with step 110 in which a substrate may be subject to wetting after a patterned layer has been created on the surface. In some embodiments, step 110 may include any of a series of process steps to clean or etch the wafer, for example, the standard RCA clean.

At step 120, a first rinsing agent may be applied to the substrate surface containing the preformed patterned layer. The most commonly used first rinsing agent in the semiconductor industry is water. For example, water may be used to remove any remaining active chemicals (such as acids, surfactants, and etc.) from the wafer and patterns.

During the water rinse step, the wafer surface is maintained in a wetted state so as to ensure no portion of the wafer is allowed to dry prior to the final controlled-drying process.

At step 210, the wetted substrate surface may be subject to a combined process including both solvent displacement (e.g., step 210-A) and silylation (e.g., step 210-B). This may occur before the substrate and patterned layer are allowed to dry from the rinsing step 120. At step 210-A, a second rinsing agent (e.g., an organic solvent such as IPA) may be applied to the substrate surface that is already wetted with a first rinsing agent (e.g., water). The second rinsing agent may be miscible with the first rinsing agent. After the second rinsing agent is applied, it may readily enter the space between miniaturized structures in the patterned layer that has been occupied by the first rinsing agent and displaces at least some of the first rinsing agent. In the case of water and IPA, the space between miniaturized structures in the patterned layer may now be occupied by a solution of IPA in water, which evaporates much more easily than water does.

At step 210-B, a gas stream containing a vaporized silylation agent and nitrogen may be applied to the same location on substrate surface where the second rinsing agent is applied. In some embodiments, the gas stream may serve multiple functions. The gas stream may promote evaporation of either the first or second rinsing agent, or the mixed solution of both. The gas stream may also physically push any liquid rinsing agent towards and off the edge of the substrate surface to facilitate drying. The vaporized silylation agent may react with functional groups (e.g., hydroxyl groups) on the substrate surface to result in a silylated surface that has improved high contact angels. Nitrogen may be a carrier gas to promote vaporization of the liquid silylation agent. Nitrogen itself is a very stable gas and may not interfere with the silylation reaction.

In some embodiments, IPA rinse and silylation may take place almost simultaneously. In some embodiments, silylation may take place shortly after IPA rinse initiates.

In some embodiments, wetting of the substrate surface (e.g., performed at steps 110 and 120) may be performed separately, for example, in a different location or at a different time. Essentially, the combined solvent displacement and silylation step may be directly applied to substrate surfaces that are already wetted.

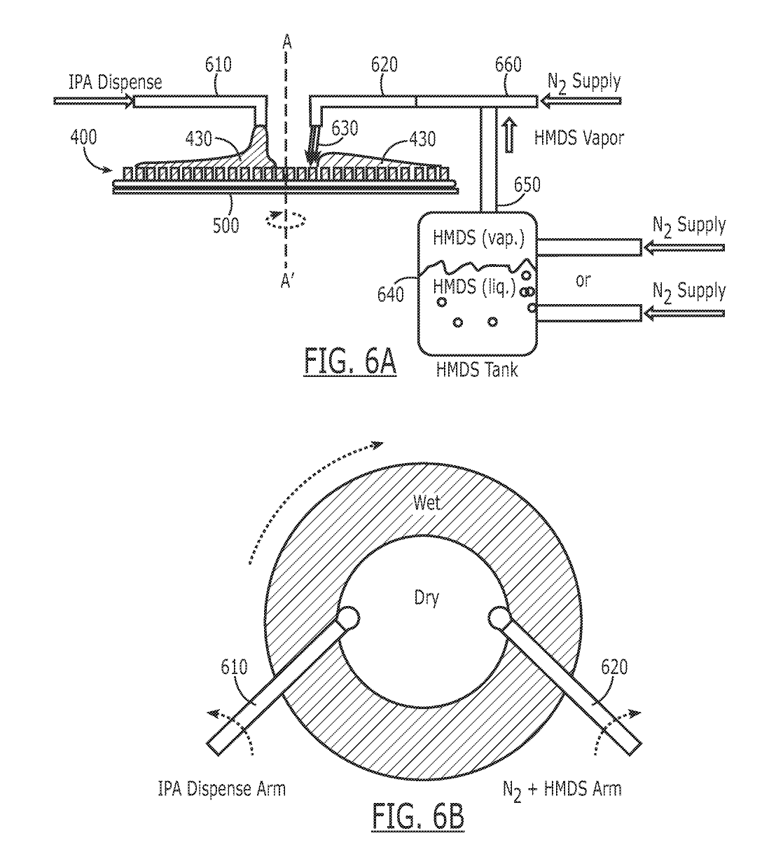

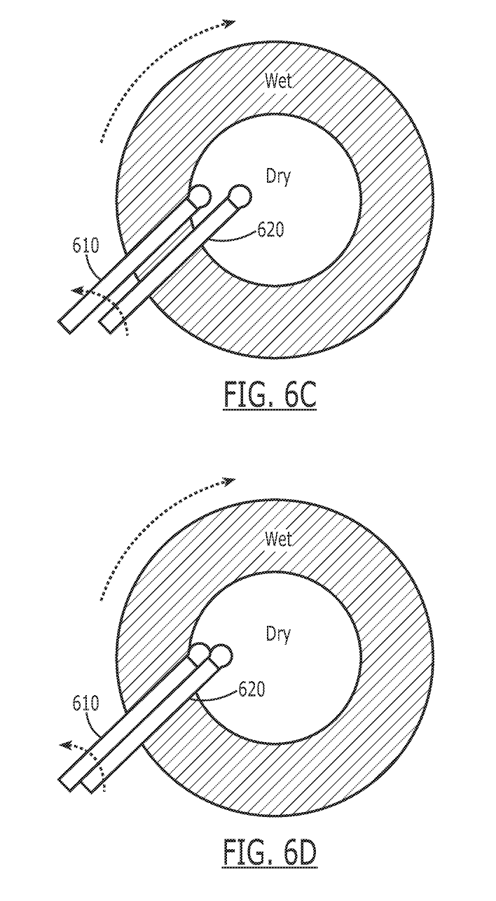

The nitrogen stream may be used to skim off a volatile component vapor phase of the silyl agent above or beneath the liquid surface in a liquid storage tank, as is shown, for example, in FIG. 6A. This may be accomplished by flowing nitrogen across the liquid surface inside a partially filled liquid storage tank or by introducing the nitrogen at a point above the liquid surface, or alternatively by introducing the nitrogen into the storage tank below the liquid surface and allowing the nitrogen to bubble through the liquid before exiting the storage tank as a nitrogen purge gas flow enriched with silylating agent vapor. The silylating chemistry may include HMDS, TMSDMA, or similar materials listed below. The silylating agent may replace a hydrophilic terminating group at the wafer material surface with a hydrophobic organic group. During rinse 120 and rinse 210-A, the substrate may be rotated.

Similarly, in some embodiments, before the combined steps 210-A and 210-B, one or more additional rinsing steps may be applied, using the first, second or both rinsing agents. In some embodiments, a third rinsing agent may be used.

After the combined rinsing and silylation step 210, the substrate may be subject to a spin-dry step 1000. Here, the substrate may be placed on a spinning platform. When the platform spins, the rinsing agent may escape from the space between the miniaturized structures in the patterned layer and result in a dry substrate bearing clean miniaturized structures. In some embodiments, a gas stream (e.g., nitrogen N₂) may be applied in the drying step to push the liquid rinsing agent off the substrate surface and also enhance evaporation of the liquid.

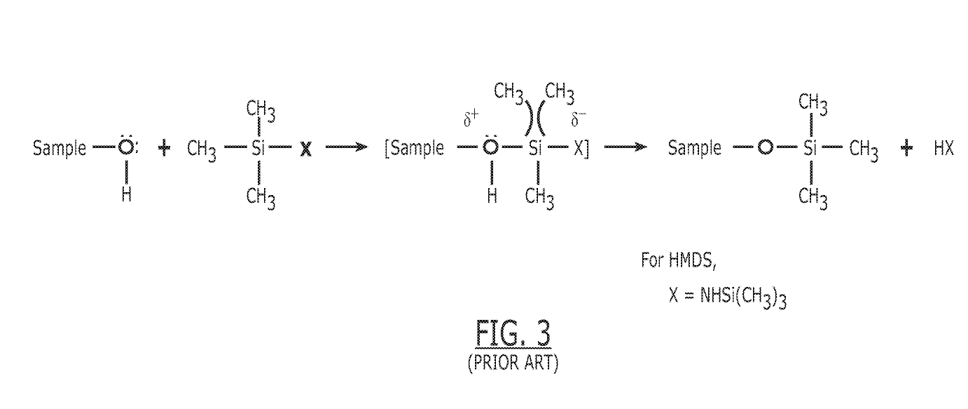

As noted above, silylation may alter properties of the substrate surface such that miniaturized structures in the patterned layer are less likely to be damaged. An exemplary silylation reaction is illustrated in FIG. 3.

During the reaction, a silylation agent may react with a functional group such as a hydroxyl group on a target sample. In this case, the silylation agent HMDS (hexamethyldisilazane) may react with hydroxyl groups of a sample to form a hydrophobic bond to the sample surface (e.g., in a Sample-O—Si—R₃ motif).

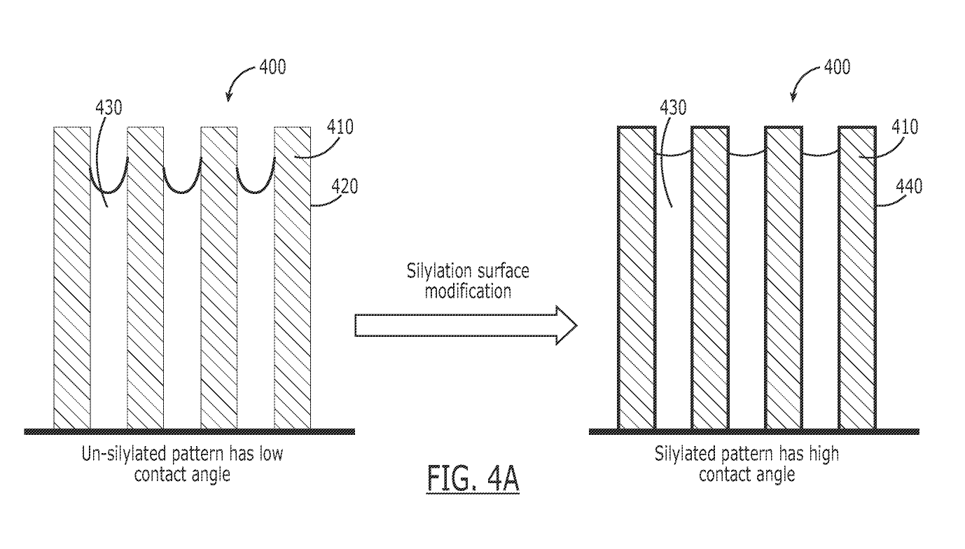

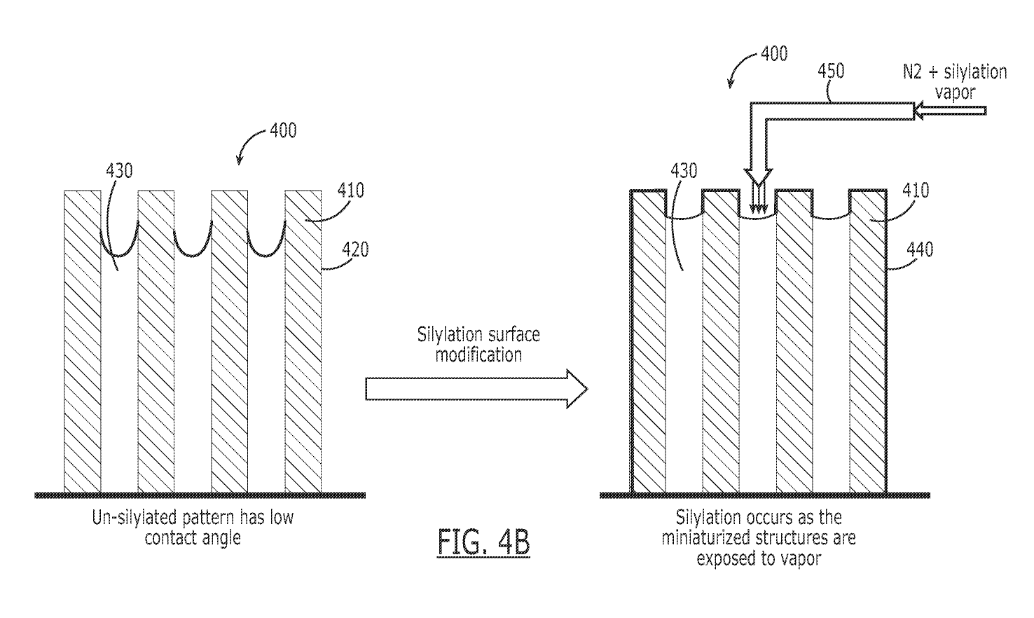

Further disclosed herein are methods of surface modification by silylation using a combined solvent displacement and vapor silylation process (e.g., the one depicted in FIG. 2). Detailed mechanism is illustrated in FIG. 4B. As described hereinabove, un-silylated miniaturized structures 410 may form low contact angles with rinsing agents and result in capillary and Laplace collapse forces that may eventually cause the miniaturized structures to collapse.

In some embodiments, after the initial washing step by a first rinsing agent (e.g., water in step 120 in FIG. 2), IPA rinse, silylation by vaporized silylating agent, and drying by a gas stream of the vaporized silylating agent and nitrogen may take place in a single combined step. In some embodiments, IPA rinse may be applied first, slightly before silylation and drying. In some embodiments, IPA rinse, silylation and drying may be applied at the same time.

In the combined solvent displacement and vapor silylation process, silylation may take place as the second rinsing agent is dried or pushed off the substrate surface to reveal miniaturized structures 410. After or at the same time when a second rinsing agent may be applied (e.g., IPA in step 210-A in FIG. 2), a gas dispense arm 450 may dispense a mixture of a vaporized silylating agent and nitrogen. The gas stream may speed up drying of the second rinsing agent to expose miniaturized structures 410.

Once the miniaturized structures are exposed, vaporized silylating agent in the mixed gas stream may modify the exposed surface of the miniaturized structures to render it more hydrophobic (e.g., modified surface 440). Silylation may progress as the level of the second rinsing agent decreases. This way, contact angle between the miniaturized structures and rinsing agent may be kept high, thus maintaining low surface tension and smaller capillary and Laplace collapse forces to avoid any damages to the miniaturized structures.

After silylation modification, the resulting surface may have a more hydrophobic surface energy, a higher water-wetting contact angle, and thus a lower capillary force on the structure which allows a higher aspect ratio structure to be wetted and dried without collapsing (see FIG. 4B).

Exemplary silylating agents may include but are not limited to TMSDMA (N-Trimethylsilyldimethylamine), HMDS (Hexamethyldisilazane), or other similar silyl chemistries that replace a hydrophilic Si—OH bond with a hydrophobic Si—O—R bond, where R can be any organic functional group, but typically is a —CH3 methyl group (see FIG. 2). Further silylation agents besides HMDS and TMSDMA include but are not limited to Allyltrimethylsilane, N,O-Bis(trimethylsilyl)acetamide (BSA), N,O-Bis(trimethylsilyl)carbamate (BSC), N,N-Bis(trimethylsilyl)formamide (BSF), N,N-Bis(trimethylsilyl)methylamine, Bis(trimethylsilyl) sulfate (BSS), N,O-Bis(trimethylsilyl)trifluoroacetamide (BSTFA), N,N′-Bis(trimethylsilyl)urea (BSU), (Ethylthio)trimethylsilane, Ethyl trimethylsilylacetate (ETSA), Hexamethyldisilane, Hexamethyldisiloxane (HMDSO), Hexamethyldisilthiane, (Isopropenyloxy)trimethylsilane (IPOTMS), 1-Methoxy-2-methyl-1-trimethylsiloxypropene, (Methylthio)trimethylsilane, Methyl 3-trimethylsiloxy-2-butenoate, N-Methyl-N-trimethylsilylacetamide (MSA), Methyl trimethylsilylacetate, N-Methyl-N-trimethylsilylheptafluorobutyramide (MSHFBA), N-Methyl-N-trimethylsilyltrifluoroacetamide (MSTFA), (Phenylthio)trimethylsilane, Trimethylbromosilane (TMBS), Trimethylchlorosilane (TMCS), Trimethyliodosilane (TMIS), 4-Trimethylsiloxy-3-penten-2-one (TMSacac), N-(Trimethylsilyl)acetamide (TMS-acetamide), Trimethylsilyl acetate, Trimethylsilyl azide, Trimethylsilyl benzenesulfonate, Trimethylsilyl cyanide (TMSCN), N-(Trimethylsilyl)diethylamine (TMSDEA), Trimethylsilyl N,N-dimethylcarbamate (DMCTMS), 1-(Trimethylsilyl)imidazole (TMSIM), Trimethylsilyl methanesulfonate, 4-(Trimethylsilyl)morpholine, 3-Trimethylsilyl-2-oxazolidinone (TMSO), Trimethylsilyl perfluoro-1-butanesulfonate (TMS nonaflate), Trimethylsilyl trichloroacetate, Trimethylsilyl trifluoroacetate, Trimethylsilyl trifluoromethanesulfonate (TMS triflate), or a mixture of two or more thereof.

FIGS. 6A and 6B illustrate a system set up for facilitating a combined solvent displacement and vapor silylation process. In the exemplary configuration in FIG. 6A, a rinsing agent 430 such as IPA may be dispensed from dispense arm 610 onto a substrate bearing a patterned layer of miniaturized structures (e.g., element 400). Simultaneously or shortly after the rinsing agent 430 is dispensed, a mixed gas stream 630 containing vaporized silylation agent and nitrogen may be applied to dry off the rinsing agent.

The mixed gas stream 630 may be generated by an exemplary vapor generating tank 640 as illustrated in FIG. 6A. In some embodiments, the vapor generating tank 640 may contain a liquid silylating agent (e.g., HMDS) and temperature may be controlled to allow the liquid silylating agent to evaporate into gas form. In some embodiments, a carrier gas (nitrogen) may be added to the vaporizing tank to create the mixed gas stream 630 containing both vaporized silylation agent and nitrogen. In some embodiments, the carrier gas may be added to the vaporization tank, directly to the liquid silylating agent, to create gas bubbles into which vaporized silylating agent will merge, thereby forming a mixed vaporized silylation agent and nitrogen. In some embodiments, the carrier gas may be added to the vaporization tank and may pass above the surface of the liquid silylating agent such that vapor escaping from the liquid silylating agent will mix with the carrier gas to form a mixed vaporized silylation agent and nitrogen. Alternatively, liquid silylating agent may be sprayed into the purge gas. In these embodiments, nitrogen and vaporized silylating agent may be mixed by the time they enter port 650. Of course, any combination of these techniques may be employed.

Alternatively, in other embodiments, the carrier gas may not be added to the vaporization tank. Instead, nitrogen may be supplied via a different port 660 and then mixed with the vaporized silylation agent in dispense arm 620. Alternatively, the mixed vaporized silylating agent and nitrogen from port 150 may be mixed with nitrogen in a manifold associated with port 660.

In some embodiments, the enriched nitrogen purge gas stream may be used to apply a shearing force to the liquid meniscus of a partially wetted wafer.

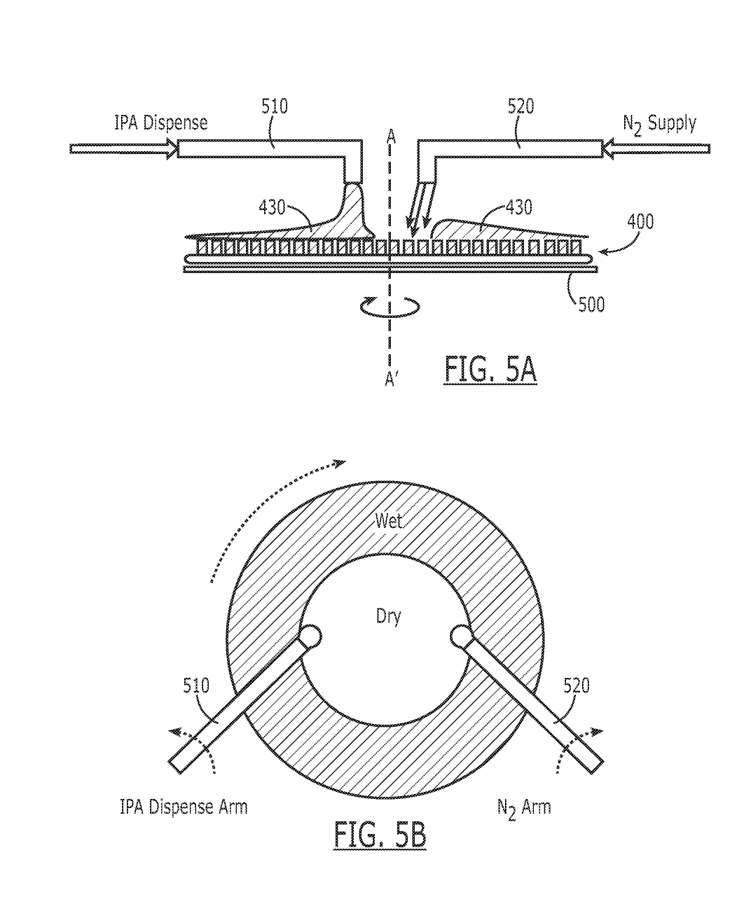

FIG. 6B shows a top view of the substrate during the rinsing and drying steps that is similar to the configuration shown in FIG. 5B. As the substrate spins and the nitrogen dispense arm moves from the center towards the edge of the substrate, the dry area may expand outward from the center while the wet area decreases and eventually disappears.

In some embodiments, the two dispense arms 610 and 620 may be positioned on the same side of the substrate adjacent to each other as illustrated in FIG. 6C. In some embodiments, the movements of the two dispense arms may be synchronized such that the nitrogen and silylating agent dispense arm moves after the IPA dispensing arm and at the same pace. In some embodiments, the movements of the two dispense arms may be synchronized such that the nitrogen and silylating agent dispense arm moves after the IPA dispensing arm but at a slower pace.

In some embodiments, the two dispense arms 610 and 620 may form two channels of the same structure. For example, as illustrated in FIG. 6D, they may be two tubes within the same dispensing arm, each connected to a different material source: one to a rinsing agent and the other to a supplier of a mixed gas source containing both vaporized silylation agent and nitrogen.

While one or both of dispense arms 610 and 620 are being used the flow rate of the purge gas or the silylation agent, the pressure of the purge gas or the silylation agent, the chemical composition of the purge gas or the silylation agent, the temperature of the purge gas or the silylation agent, the flow rate of rinsing agent 430, the temperature rinsing agent 430, the rotation speed of the substrate, the position of dispense arm 610 or dispense arm 620 or the speed of dispense arm 610 or dispense arm 620, or any combination thereof may be varied. This may be accomplished with a controller that controls the components of the system.

Having described numerous embodiments in detail, it will be apparent that modifications, variations, and equivalent embodiments are possible without departing the scope of the invention defined in the appended claims. Furthermore, it should be appreciated that all examples in the present disclosure are provided as non-limiting examples.

The various methods and techniques described above provide numerous embodiments. Of course, it is to be understood that not necessarily all objectives or advantages described may be achieved in accordance with any particular embodiment described herein. Thus, for example, those skilled in the art will recognize that the methods can be performed in a manner that achieves or optimizes one advantage or group of advantages as taught herein without necessarily achieving other objectives or advantages as may be taught or suggested herein. A variety of advantageous and disadvantageous alternatives are mentioned herein. It is to be understood that some embodiments specifically include one, another, or several advantageous features, while others specifically exclude one, another, or several disadvantageous features, while still others specifically mitigate a present disadvantageous feature by inclusion of one, another, or several advantageous features.

Furthermore, the skilled artisan will recognize the applicability of various features from different embodiments. Similarly, the various elements, features and steps discussed above, as well as other known equivalents for each such element, feature or step, can be mixed and matched by one of ordinary skill in this art to perform methods in accordance with principles described herein. Among the various elements, features, and steps some will be specifically included and others specifically excluded in diverse embodiments.

Although the invention has been disclosed in the context of certain embodiments and examples, it will be understood by those skilled in the art that the embodiments of the invention extend beyond the specifically disclosed embodiments to other alternative embodiments and/or uses and modifications and equivalents thereof

In some embodiments, the numbers expressing quantities of ingredients, properties such as molecular weight, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

In some embodiments, the terms “a” and “an” and “the” and similar references used in the context of describing a particular embodiment of the invention (especially in the context of certain of the following claims) can be construed to cover both the singular and the plural. The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

1. A method, comprising:
rinsing a substrate having a patterned layer formed thereupon, wherein the substrate and patterned layer are wetted by a first rinsing agent, by dispensing a second rinsing agent thereupon, to displace the first rinsing agent; and
simultaneously with or immediately following the rinsing step, exposing the substrate and the patterned layer to a mixture of a purge gas and a vaporized silylation agent, to displace the second rinsing agent and dry the substrate,
wherein the substrate and patterned layer are not allowed to dry between the first and second rinsing steps and the second rinsing agent displaces the first rinsing agent.

2. The method of claim 1, further comprising:
in a prior rinsing step, rinsing the substrate and patterned layer by dispensing the first rinsing agent thereupon.

3. The method of claim 1, wherein during the rinsing step, a predetermined and gradually-changing amount of first rinsing agent is blended into the second rinsing agent, such that at the end of the rinsing step, only the second rinsing agent is dispensed onto the substrate.

4. The method of claim 1, wherein the first rinsing agent comprises deionized water.

5. The method of claim 1, wherein the second rinsing agent comprises isopropyl alcohol.

6. The method of claim 1, wherein the purge gas comprises nitrogen, an inert gas, or a mixture thereof.

7. The method of claim 1, wherein the vaporized silylation agent comprises Allyltrimethylsilane, N,O-Bis(trimethylsilyl)acetamide (BSA), N,O-Bis(trimethylsilyl)carbamate (BSC), N,N-Bis(trimethylsilyl)formamide (BSF), N,N-Bis(trimethylsilyl)methylamine, Bis(trimethylsilyl) sulfate (BSS), N,O-Bis(trimethylsilyl)trifluoroacetamide (BSTFA), N,N′-Bis(trimethylsilyl)urea (BSU), (Ethylthio)trimethylsilane, Ethyl trimethylsilylacetate (ETSA), Hexamethyldisilane, Hexamethyldisilazane (HMDS), Hexamethyldisiloxane (HMDSO), Hexamethyldisilthiane, (Isopropenyloxy)trimethylsilane (IPOTMS), 1-Methoxy-2-methyl-1-trimethylsiloxypropene, (Methylthio)trimethylsilane, Methyl 3-trimethylsiloxy-2-butenoate, N-Methyl-N-trimethylsilylacetamide (MSA), Methyl trimethylsilylacetate, N-Methyl-N-trimethylsilylheptafluorobutyramide (MSHFBA), N-Methyl-N-trimethylsilyltrifluoroacetamide (MSTFA), (Phenylthio)trimethylsilane, Trimethylbromosilane (TMBS), Trimethylchlorosilane (TMCS), Trimethyliodosilane (TMIS), 4-Trimethylsiloxy-3-penten-2-one (TMSacac), N-(Trimethylsilyl)acetamide (TMS-acetamide), Trimethylsilyl acetate, Trimethylsilyl azide, Trimethylsilyl benzenesulfonate, Trimethylsilyl cyanide (TMSCN), N-(Trimethylsilyl)diethylamine (TMSDEA), N-(Trimethylsilyl)dimethylamine (TMSDMA), Trimethylsilyl N,N-dimethylcarbamate (DMCTMS), 1-(Trimethylsilyl)imidazole (TMSIM), Trimethylsilyl methanesulfonate, 4-(Trimethylsilyl)morpholine, 3-Trimethylsilyl-2-oxazolidinone (TMSO), Trimethylsilyl perfluoro-1-butanesulfonate (TMS nonaflate), Trimethylsilyl trichloroacetate, Trimethylsilyl trifluoroacetate, Trimethylsilyl trifluoromethanesulfonate (TMS triflate), or a mixture of two or more thereof.

8. The method of claim 1, wherein the mixture of the purge gas and vaporized silylation agent is formed by bringing into fluid contact a flow of purge gas and the silylation agent in liquid form.

9. The method of claim 8, wherein the bringing into contact the flow of purge gas and the silylation agent in liquid form comprises flowing the purge gas through the liquid silylation agent stored in an evaporator vessel.

10. The method of claim 8, wherein the bringing into contact the flow of purge gas and the silylation agent in liquid form comprises flowing the purge gas across an exposed free surface of the liquid silylation agent stored in an evaporator vessel.

11. The method of claim 8, wherein the bringing into contact the flow of purge gas and the silylation agent in liquid form comprises spraying the liquid silylation agent into the purge gas.

12. The method of claim 1, further comprising:
rotating the substrate during the first and second rinsing steps.

13. The method of claim 1, further comprising:
during the second rinsing step, moving a first nozzle for dispensing the second rinsing agent from an position substantially at the center of the substrate towards the substrate edge.

14. The method of claim 1, further comprising:
during the second rinsing step, moving a purge nozzle for injecting the mixture of the purge gas and the vapor silylation agent from a position substantially at the center of the substrate towards the substrate edge.

15. The method of claim 1, wherein at least one parameter selected from the group consisted of purge gas and the vapor silylation agent mixture flowrate, purge gas and the vapor silylation agent mixture pressure, purge gas and the vapor silylation agent chemical composition, purge gas and the vapor silylation agent mixture temperature, second rinsing agent flowrate, second rinsing agent temperature, and substrate rotation speed, first nozzle position, first nozzle speed, purge nozzle position, and purge nozzle speed are varied during the second rinsing step or the exposing step.

16. An apparatus, comprising:
a substrate holder;
a first nozzle constructed and arranged to dispense a second rinsing agent onto a substrate on the substrate holder;
a purge nozzle constructed and arranged to direct a mixture of a purge gas and a vapor silylation agent onto the substrate; and
a mixture supply system, constructed and arranged to supply the purge nozzle with the mixture of the purge gas and the vapor silylation agent, comprising:
a purge gas supply;
an evaporator vessel for storing a silylation agent in liquid form, the evaporator vessel being constructed and arranged to form the vapor silylation agent by bringing into fluid contact a first flow of purge gas and the silylation agent in liquid form; and
a manifold constructed and arranged to form forming the mixture of the purge gas and the vapor silylation agent by mixing the first flow of purge gas and the vapor silylation agent, with a second flow of purge gas, and for supplying the mixture of the purge gas and the vapor silylation agent to the purge nozzle.

17. The apparatus of claim 15, wherein the first flow of purge gas and the silylation agent in liquid form are brought into contact by flowing the first flow of purge gas through the silylation agent in liquid form that is stored in an evaporator vessel.

18. The apparatus of claim 16, wherein the first flow of purge gas and the silylation agent in liquid form are brought into contact by flowing the first flow of purge gas across an exposed free surface of the silylation agent in liquid form that is stored in an evaporator vessel.

19. The apparatus of claim 16, wherein the first nozzle is movable along a path starting substantially at the center of the substrate and directed towards the edge of the substrate.

20. The apparatus of claim 16, wherein the purge nozzle is movable along a path starting substantially at the center of the substrate and directed towards the edge of the substrate.

21. The apparatus of claim 16, wherein the purge nozzle is movable independent of the first nozzle.

22. The apparatus of claim 16, further comprising:
a controller configured for controlling and varying at least one parameter selected from the group consisted of purge gas and the vapor silylation agent mixture flowrate, purge gas and the vapor silylation agent mixture pressure, purge gas and the vapor silylation agent chemical composition, purge gas and the vapor silylation agent mixture temperature, second rinsing agent flowrate, second rinsing agent temperature, substrate rotation speed, first nozzle position and speed, and purge nozzle position and speed.
